(19) United States
(12) Patent Application Publication
(10) Pub. No.: US 2011/0147848 A1
(43) Pub. Date: Jun. 23, 2011

(54) Multiple transistor fin heights

(76) Inventors: Kelin J. Kuhn, Aloha, OR (US); Tahir Ghani, Portland, OR (US); Justin S. Sandford, Tigard, OR (US)

(21) Appl. No.: 12/655,085

(22) Filed: Dec. 23, 2009

(51) Int. Cl. H01L 27/088; H01L 21/762

(52) U.S. Cl. 257/368; 438/424; 257/E27.06; 257/E21.546

(57) ABSTRACT

The present disclosure relates to the field of fabricating microelectronic devices. In at least one embodiment, the present subject matter relates to forming transistor fins of differing heights to obtain a performance improvement for a given type of integrated circuit within the microelectronic device.

### BACKGROUND OF THE INVENTION

Microelectronic integrated circuits, such as microprocessors, comprise literally hundreds of millions of transistors. The speed of the integrated circuits is primarily dependent on the performance of these transistors. Thus, the industry has developed unique structures, such as non-planar transistors, transistors to improve performance.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a perspective view of non-planar transistors having multiple transistor fin heights;

FIG. 2 is a side cross-sectional view of three transistor fins of differing heights;

FIGS. 3a-3j are side cross-sectional views of forming transistor fins of differing heights; and

FIG. 4 is a flow diagram of the process of FIGS. 3a-3j.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

In the fabrication of non-planar transistors, such as tri-gate transistors and FinFETs, non-planar semiconductor bodies may be used to form transistors capable of full depletion with very small gate lengths (e.g., less than about 30 nm). These semiconductor bodies are generally fin-shaped and are, thus, generally referred to as transistor “fins”. For example in a tri-gate transistor, the transistor fins have a top surface and two opposing sidewalls formed on a bulk semiconductor substrate or a silicon-on-insulator substrate. A gate dielectric may be formed on the top surface and sidewalls of the semiconductor body and a gate electrode may be formed over the gate dielectric on the top surface of the semiconductor body and adjacent to the gate dielectric on the sidewalls of the semiconductor body. Thus, since the gate dielectric and the gate electrode are adjacent to three surfaces of the semiconductor body, three separate channels and gates are formed. As there are three separate channels formed, the semiconductor body can be fully depleted when the transistor is turned on. With regard to finFET transistors, the gate material and the electrode only contact the sidewalls of the semiconductor body, such that two separate channels are formed (rather than three in tri-gate transistors).

Embodiments of the present description relate to the fabrication of microelectronic devices. In at least one embodiment, the present subject matter relates to forming transistor fins of differing heights to obtain improved performance for a given type of circuit within the microelectronic device.

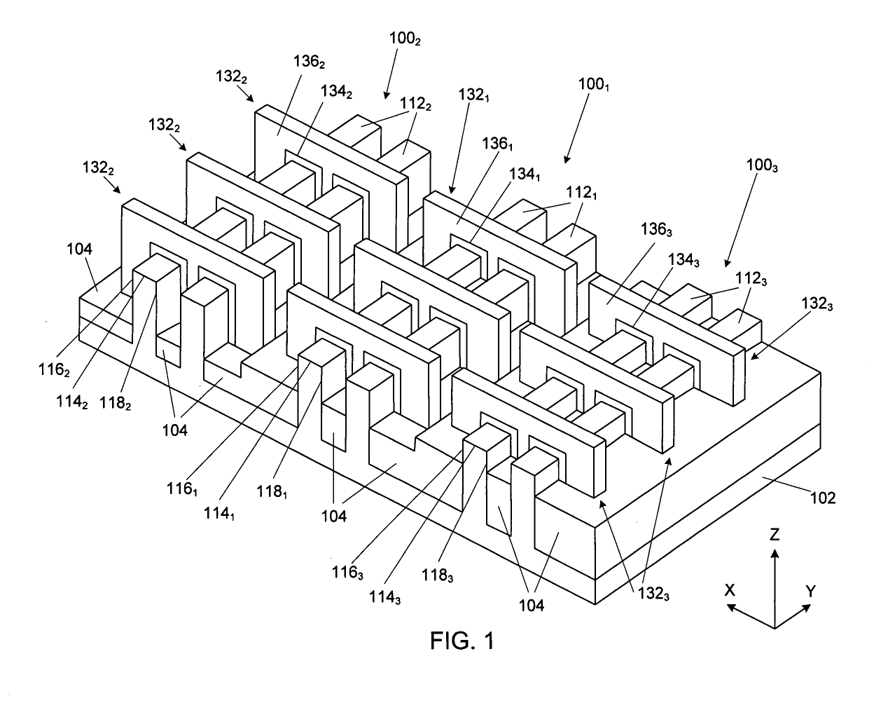

FIG. 1 is a perspective view of a number of transistor sets 100₁, 100₂, and 100₃, including a number gates formed on transistor fins, which are formed on a substrate. In an embodiment of the present disclosure, a substrate 102 may be a monocrystalline silicon substrate. The substrate 102 may also be other types of substrates, such as silicon-on-insulator (“SOI”), germanium, gallium arsenide, indium antimonide, lead telluride, indium arsenide, indium phosphide, gallium arsenide, gallium antimonide, and the like, any of which may be combined with silicon.

Each transistor set 100₁, 100₂, 100₃, shown as tri-gate transistors, includes transistor fins 112₁, 112₂, 112₃ which may have isolation regions 104, such as silicon oxide (SiO₂) between each of the transistor fins 112₁, 112₂, 112₃, as well as between the transistor sets 100₁, 100₂, 100₃ themselves. The isolations regions 104 may be formed by forming trenches in the substrate 102, then filling the trenches with an electrically insulative material, such as silicon oxide (SiO₂).

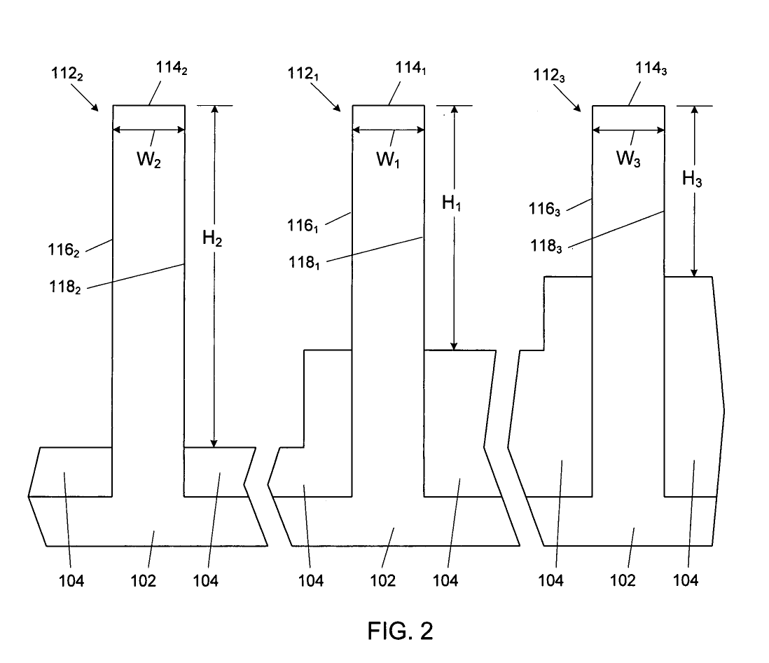

Each transistor fin 112₁, 112₂, 112₃ may have a top surface 114₁, 114₂, 114₃ and a pair of laterally opposite sidewalls, sidewalls 116₁, 116₂, 116₃ and opposing sidewall 118₁, 118₂, 118₃, respectively. As shown in FIG. 1, the transistor fins may have multiple heights (distance from the isolation region 104 to the transistor fin top surfaces 114₁, 114₂, 114₃—see FIG. 2).

As further shown in FIG. 1, at least one transistor gate 132₁, 132₂, 132₃ may be formed over each of the transistor fins 112₁, 112₂, 112₃, respectively. The transistor gates 132₁, 132₂, 132₃ may be fabricated by forming gate dielectric layers 134₁, 134₂, 134₃ on or adjacent to the transistor fin top surfaces 114₁, 114₂, 114₃ and on or adjacent to the transistor fin sidewalls 116₁, 116₂, 116₃ and transistor fin opposing sidewalls 118₁, 118₂, 118₃, and forming gate electrodes 136₁, 136₂, 136₃ on or adjacent the gate dielectric layers 134₁, 134₂, 134₃, respectively. In an implementation of the present disclosure, the transistor fins 112₁, 112₂, 112₃ run in a direction substantially perpendicular to the transistor gates 132₁, 132₂, 132₃, respectively.

The gate dielectric layers 134₁, 134₂, 134₃ may be formed from any well-known gate dielectric material, including but not limited to silicon dioxide (SiO₂), silicon oxynitride (SiOₓN_{y}), silicon nitride (Si₃N₄), and high-k dielectric materials such as hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. The gate dielectric layers 134₁, 134₂, 134₃ can be formed by well-known techniques, such as by depositing a gate electrode material, such as chemical vapor deposition (“CVD”), physical vapor deposition (“PVD”), atomic layer deposition (“ALD”), and then patterning the gate electrode material with well-known photolithography and etching techniques, as will be understood to those skilled in the art.

As shown in FIG. 1, the gate electrodes 136₁, 136₂, 136₃ may be formed on or adjacent to the gate dielectric layers 134₁, 134₂, 134₃, respectively. The gate electrodes 136₁, 136₂, 136₃ can be formed by well-known techniques, such as by depositing a gate electrode material, such as chemical vapor deposition (“CVD”), physical vapor deposition (“PVD”), atomic layer deposition (“ALD”), and then patterning the gate electrode material with well-known photolithography and etching techniques, as will be understood to those skilled in the art.

The gate electrode 136₁, 136₂, 136₃ can be formed of any suitable gate electrode material. In an embodiment of the present disclosure, the gate electrodes 136₁, 136₂, 136₃ may be formed from materials that include, but are not limited to, polysilicon, tungsten, ruthenium, palladium, platinum, cobalt, nickel, hafnium, zirconium, titanium, tantalum, aluminum, titanium carbide, zirconium carbide, tantalum carbide, hafnium carbide, aluminum carbide, other metal carbides, metal nitrides, and metal oxides. The gate electrodes 136₁, 136₂, 136₃ can be formed by well-known techniques, such as by blanket depositing a gate electrode material and then patterning the gate electrode material with well-known photolithography and etching techniques, as will be understood to those skilled in the art.

It is understood that a source region and a drain region (not shown) may be formed in the transistor fins 112₁, 112₂, 112₃ on opposite sides of the gate electrodes 136₁, 136₂, 136₃, respectively. The source and drain regions may be formed of the same conductivity type, such as N-type or P-type conductivity. The source and drain regions may have a uniform doping concentration or may include sub-regions of different concentrations or doping profiles such as tip regions (e.g., source/drain extensions). In some implementations of an embodiment of the present disclosure, the source and drain regions may have the substantially the same doping concentration and profile while in other implementations they may vary.

FIG. 2 illustrates three transistor fins 112₁, 112₂, 112₃ of differing heights. The “gate width” of a transistor is equal to a height H₁, H₂, H₃ corresponding to a transistor fin sidewall 116₁, 116₂, 116₃, respectively, plus a width W₁, W₂, W₃ corresponding to a transistor fin top surface 114₁, 114₂, 114₃, respectively, plus again a height H₁, H₂, H₃ corresponding to the transistor fin opposing sidewall 118₁, 118₂, 118₃, respectively. Thus, a gate width can be generally determined by: gate width=fin width+2*fin height for tri-gate transistors. With regard to finFET transistors, only the sidewalls form channels. Thus, a finFET gate width can be generally determined by: gate width=2*fin height.

As the industry continually strives to reduce the footprint of integrated circuits (the space taken up in the x-y plane—see FIG. 1), if an increase in gate width is desired, the height of the transistor fin is increased rather than increasing the width of the transistor fin. There are two significant reasons for increasing fin height. The first reason is that an increase in drive current can be attained (without increasing the footprint) and the second is that an improved (decreased) Vccₘᵢₙ (minimum power supply voltage required to operate a device) can be attained, which is a result of the increase area of the gate from the increase in the transistor fin height. However, increasing the transistor fin height also results in an increased gate capacitance, which will result in a degradation of dynamic capacitance.

As microelectronic devices can contain numerous components, such as logic components, memory components, etc., fabrication on a single substrate, an embodiment of the present disclosure uses transistor fins of multiple heights, rather than simply finding a uniform fin height for all of the transistor components. These multiple fin heights may be used for different components or may be used within the individual or single component. Thus, the use of multiple fin heights may provide a solution to the problem of increased dynamic capacitance by matching the device fin height to the circuit requirements of specific circuits. Thus, in one embodiment of the present description, multiple height fins for trigate or FinFET transistors are used to obtain the high performance and drive current and low Vccₘᵢₙ, leakage, low capacitance, and low dynamic energy.

Referring to FIG. 2, the transistor fin 112₁ will be referred to as “nominal”, the transistor fin 112₂ will be referred to as “tall”, and the transistor fin 112₃ will be referred to as “short”.

In one embodiment of the present disclosure, the nominal transistor fin 112₁ can be set as the transistor fin that delivers baseline performance for the microelectronic device and may be selected for increased current drive, but increased capacitance. The nominal transistor 112₁ may be utilized in integrated circuits with high interconnect loads (e.g., C_{ic}>C_{gate}). The nominal transistor 112₁ (or the tall transistor 112₂) may be utilized in integrated circuit components, such as repeaters or drivers, where the total interconnect load of the connecting lines (e.g., traces or wires connecting separate components or integrated circuits within a component) is greater than the total capacitive load of the microelectronic device. In other words, integrated circuits having total capacitive load less than the total interconnection of connecting lines within the microelectronic device.

The tall transistor fin 112₂, as previously discussed, has the advantage of reduced Vccₘᵢₙ and improved drive, but the limitation of increased capacitance, and thus has a different performance from the baseline performance for the microelectronic device. The tall transistor fin 112₂ may be utilized in integrated circuit components such as static random access memories (SRAM) and register file circuits, where it is important to achieve low Vccₘᵢₙ. The option for combinations of device heights also provides additional tuning granularity, particularly for Vccₘᵢₙ increasing performance in register files.

The short transistor fin 112₃ has lower performance (or low leakage) in comparison to the nominal fin 112₁ (baseline performance) and the performance of the tall transistor fin 112₂, but has the benefit of lower capacitance and reduced dynamic energy and would be used for integrated circuit components, such as register files, latches, or complex gates with high fanout, where the total capacitive load of the device is greater than the total interconnect load of the connecting wires. As will be understood to those skilled in art, the short transistor fin 112₃ could also be increased in leakage, thus delivering equivalent performance at increased leakage, but reduced capacitance.

In an additional embodiment, combinations of device heights provides a means for having multiple gate widths in a integrated circuit within a component without introducing undesirable diffusion jogs, as will be understood to those skilled in the art.

In one embodiment of the present description, the fin heights can be sized from the nominal transistor fin height H₁. For the tall transistor 112₂, the transistor fin height H₂ may be between about 1.2 and 1.6 times the nominal transistor fin height H₁, and in a specific embodiment about 1.4 times the nominal transistor fin height H₁. For the short transistor 112₃, the transistor fin height H₃ may be between about 0.85 and 0.5 times the nominal transistor fin height H₁, and in a specific embodiment about 0.7 times the nominal transistor fin height H₁. A transistor fin height H₂ of 1.2 to 1.6 times the nominal transistor fin height H₁ represents the tallest fin height that may still deliver delay performance improvement in a typical circuit network. Transistor fins greater than about 1.6 times the nominal transistor fin height H₁ may introduce too much capacitive loss from the transistor fin, such that no significant delay improvement may be achieved. The nominal fin delivers delay performance improvement, but not dynamic energy improvement, while the fin height of about 0.85 to 0.5 times the nominal transistor fin height H₁ simultaneous delivers delay and capacitance improvement. Transistor fin heights less than about 0.5 times the nominal transistor fin height H₁ may provide dynamic energy improvement, but may not improve delay performance.

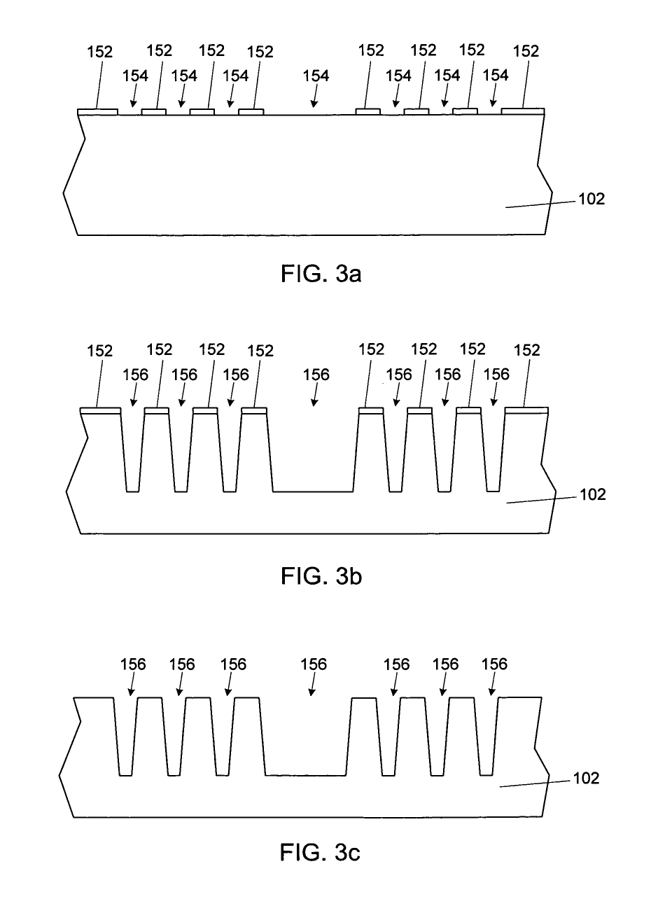

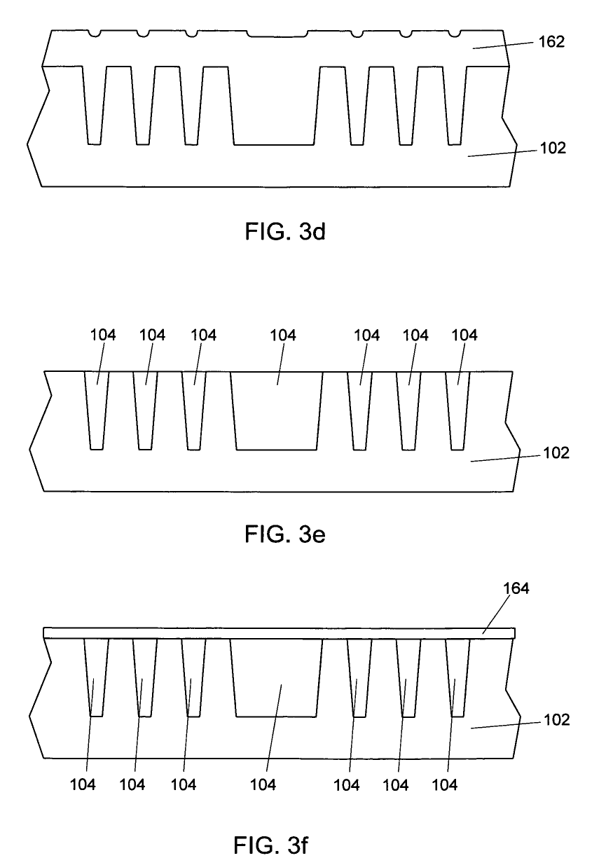

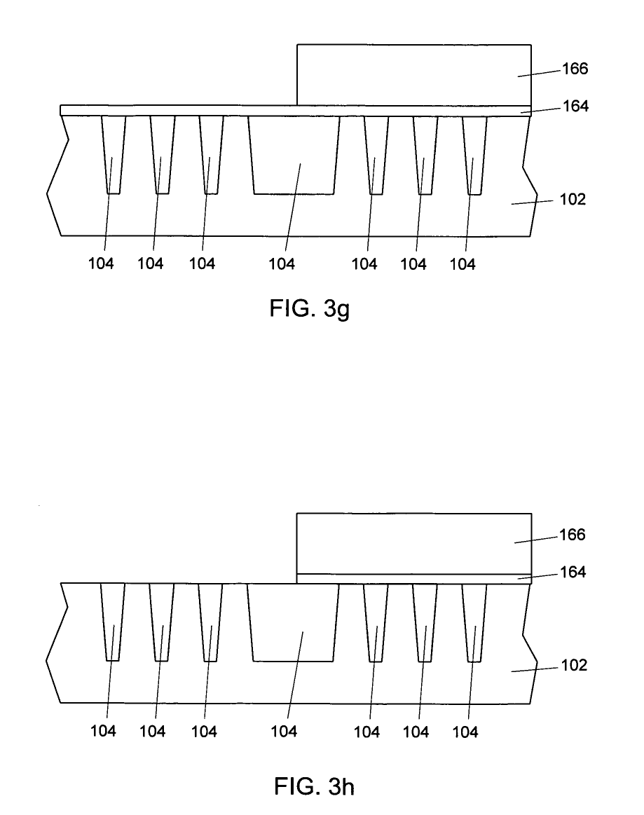

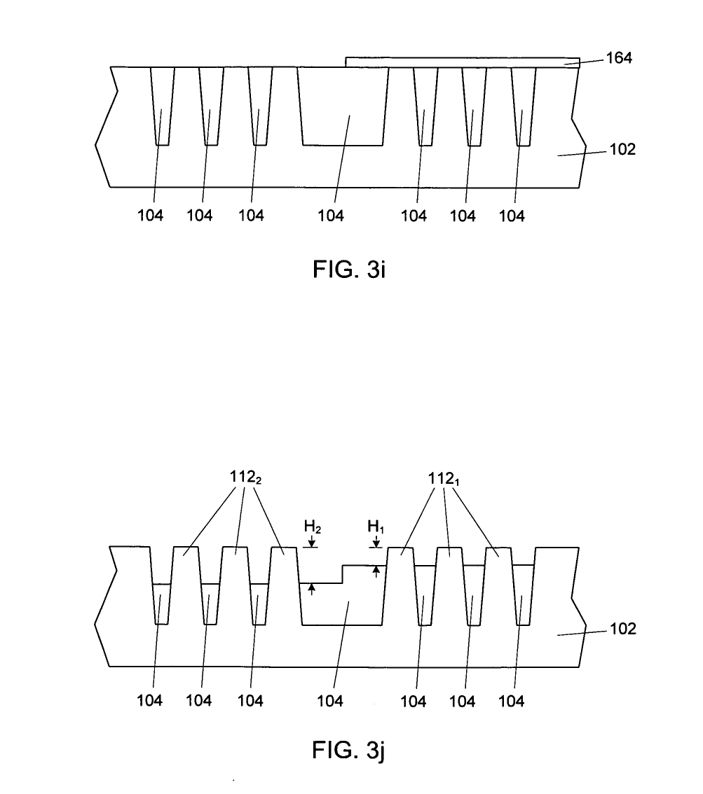

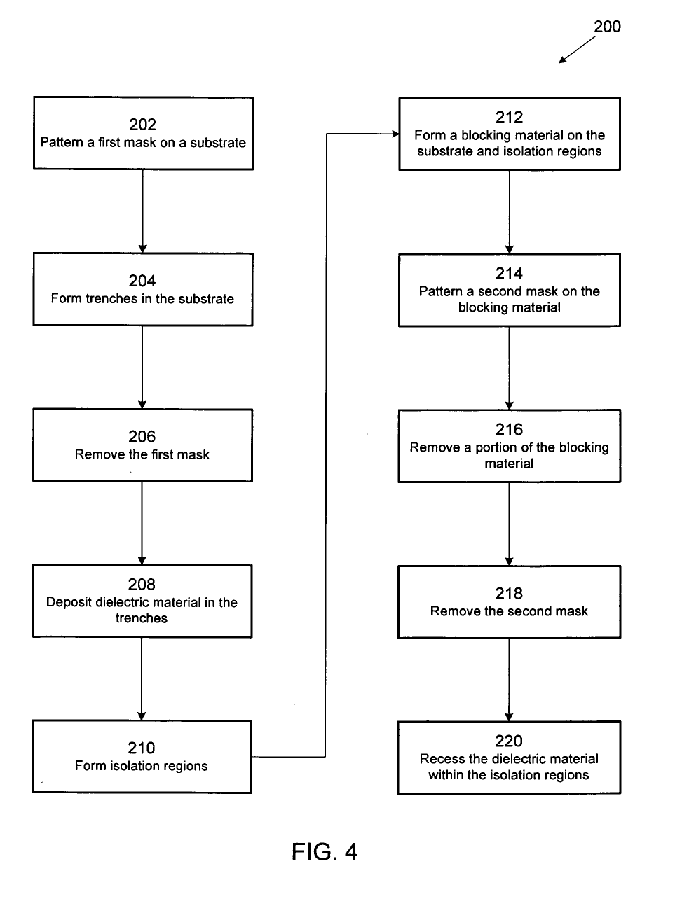

FIGS. 3a-3j illustrate cross-sections of structures that are formed when the method 200 of FIG. 4 is carried out. As shown in FIG. 3a, the substrate 102 has a first mask 152 patterned on the substrate 102 (block 202 of FIG. 4), wherein the first mask 152 is patterned with a plurality of openings 154 which exposes portions of the substrate 102. The first mask 152 may be any appropriate material, such as a photoresist material.

As shown in FIG. 3b, a plurality of trenches 156 may be formed in the substrate 102 (block 204 of FIG. 4), such as by etching. In one embodiment, the etching can be achieved by a reactive ion etch in a carbon tetrafluoride (“CF₄”)/chlorine (“Cl₂”) gas mixture. In an embodiment, the etching can be achieved by either a wet or dry etch. In another embodiment, the etching may be achieved with a hydrofluoric acid solution, potassium hydroxide solution, tetramethylammonium hydroxide solution, and the like. After etching, the first mask 152 is removed (block 206 of FIG. 4), as shown in FIG. 3c. The removal of the mask may be achieved by an ashing and clean process, as will be understood to those skilled in the art. It is understood that the masking and etching steps for FIGS. 3a and 3b can be replaced by an ablation technique, such as laser or ion ablation.

As shown in FIG. 3d, a dielectric material 162 may be deposited in the trenches 156 (see FIG. 3c) (block 208 of FIG. 4). The dielectric material may be any appropriate material, including but not limited to, silicon oxide (e.g., SiO₂). The dielectric material may be deposited by any known technique, including, but not limited to chemical vapor deposition (“CVD”), physical vapor deposition (“PVD”), atomic layer deposition (“ALD”), and the like.

As shown in FIG. 3e, dielectric material 162 that is not within the trenches 156 (see FIG. 3c) may be removed to form the isolation regions 104 (block 210 of FIG. 4). This may be achieved by any process known in the art, including, but not limited to chemical mechanical polishing (“CMP”) and etching.

As shown in FIG. 3f, a blocking material 164 may be deposited on the substrate 102 and the isolation regions 104 (block 212 of FIG. 4). The blocking material 164 may be any appropriate material, including, but not limited to silicon nitride, and my be deposited by any known technique, including, but not limited to chemical vapor deposition (“CVD”), physical vapor deposition (“PVD”), atomic layer deposition (“ALD”), and the like.

A second mask 166 may be patterned on the blocking material 164 (block 214 of FIG. 4), as shown in FIG. 3g, wherein the second mask 166 is patterned to expose at least a portion of the blocking material 164. The second mask 166 may be any appropriate material, such as a photoresist material, and may be patterned by any known lithographic technique.

As shown in FIG. 3h, a portion of the blocking material 164 not masked by the second mask 166 may be removed, such as by etching, to exposed portion of the substrate 102 and a portion of the plurality of isolation regions 104 (block 216 of FIG. 4). In an embodiment where the portion of the blocking material 164 is removed by etching, the etching technique should be selected to remove the blocking material without etching the isolation regions 104 or the substrate 102. In an embodiment wherein the blocking material is silicon nitride, the etching material may be a reactive ion etch in a carbon tetrafluoride (“CF₄”)/Trifluoromethane (“CHF₃”) gas mixture. As shown in FIG. 3i, the second mask 166 may be removed (block 218 of FIG. 4), such as by an ashing and cleaning processes, as will be understood to those skilled in the art.

As shown in FIG. 3j, the dielectric material within the isolation regions 104 is recessed (block 220 of FIG. 4), such as by wet or dry etching to forming transistor fins 112₁, 112₂. The etching process removes the blocking material 164 and the dielectric material within the isolation regions 104, while not etching the substrate 102. However, as will be understood, the etch must removed the blocking material 164 before exposing and etching the dielectric material 162 masked by the blocking material 164. Thus, the transistor fins 112₁ are shorter in height H₁, than the transistor fins 112₂ with height H₂. In an embodiment wherein the blocking material is silicon nitride, the etching material may be a 50:1 hydrofluoric acid solution. The silicon nitride to silicon oxide etch rate ratio is about 0.5, depending on the type of silicon nitride used.

The detailed description has described various embodiments of the devices and/or processes through the use of illustrations, block diagrams, flowcharts, and/or examples. Insofar as such illustrations, block diagrams, flowcharts, and/or examples contain one or more functions and/or operations, it will be understood by those skilled in the art that each function and/or operation within each illustration, block diagram, flowchart, and/or example can be implemented, individually and/or collectively, by a wide range of hardware, software, firmware, or virtually any combination thereof.

The described subject matter sometimes illustrates different components contained within, or connected with, different other components. It is understood that such illustrations are merely exemplary, and that many alternate structures can be implemented to achieve the same functionality. In a conceptual sense, any arrangement of components to achieve the same functionality is effectively “associated” such that the desired functionality is achieved. Thus, any two components herein combined to achieve a particular functionality can be seen as “associated with” each other such that the desired functionality is achieved, irrespective of structures or intermediate components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

It will be understood by those skilled in the art that terms used herein, and especially in the appended claims are generally intended as “open” terms. In general, the terms “including” or “includes” should be interpreted as “including but not limited to” or “includes but is not limited to”, respectively. Additionally, the term “having” should be interpreted as “having at least”.

The use of plural and/or singular terms within the detailed description can be translated from the plural to the singular and/or from the singular to the plural as is appropriate to the context and/or the application.

It will be further understood by those skilled in the art that if an indication of the number of elements is used in a claim, the intent for the claim to be so limited will be explicitly recited in the claim, and in the absence of such recitation no such intent is present. Additionally, if a specific number of an introduced claim recitation is explicitly recited, those skilled in the art will recognize that such recitation should typically be interpreted to mean “at least” the recited number.

The use of the terms “an embodiment,” “one embodiment,” “some embodiments,” “another embodiment,” or “other embodiments” in the specification may mean that a particular feature, structure, or characteristic described in connection with one or more embodiments may be included in at least some embodiments, but not necessarily in all embodiments. The various uses of the terms “an embodiment,” “one embodiment,” “another embodiment,” or “other embodiments” in the detailed description are not necessarily all referring to the same embodiments.

While certain exemplary techniques have been described and shown herein using various methods and systems, it should be understood by those skilled in the art that various other modifications may be made, and equivalents may be substituted, without departing from claimed subject matter or spirit thereof. Additionally, many modifications may be made to adapt a particular situation to the teachings of claimed subject matter without departing from the central concept described herein. Therefore, it is intended that claimed subject matter not be limited to the particular examples disclosed, but that such claimed subject matter also may include all implementations falling within the scope of the appended claims, and equivalents thereof.

What is claimed is:

1. A microelectronic device comprising:
a first transistor fin having a first height which sets the baseline performance for first integrated circuitry within the microelectronic device; and
a second transistor fin having a height differing from the first transistor fin height, which sets a performance for second integrated circuitry within the microelectronic device, wherein the performance for the second integrated circuitry differs from the baseline performance.

2. The microelectronic device of claim 1, wherein the second transistor fin height comprises a height of between about 1.2 and 1.6 times the first transistor fin height.

3. The microelectronic device of claim 2, wherein the second transistor fin height comprises a height of about 1.4 times the first transistor fin height.

4. The microelectronic device of claim 2, wherein the second integrated circuitry comprises a static random access memory.

5. The microelectronic device of claim 2, wherein the second integrated circuitry comprises register file circuitry.

6. The microelectronic device of claim 1, wherein the second transistor fin height comprises a height of between about 0.85 and 0.5 times the first transistor fin height.

7. The microelectronic device of claim 6, wherein the second transistor fin height comprises a height of about 0.7 times the first transistor fin height.

8. The microelectronic device of claim 6, wherein the second integrated circuitry within the microelectronic device comprises second integrated circuits having a total capacitive load of greater than the total interconnection load of connecting lines within the microelectronic device.

9. The microelectronic device of claim 8, wherein the second integrated circuits comprise register files, latches, complex gates, and circuits with high device fanout.

10. The microelectronic device of claim 1, wherein the first integrated circuitry within the microelectronic device comprises first integrated circuits having total capacitive load less than the total interconnection of connecting lines within the microelectronic device.

11. The microelectronic device of claim 10, wherein the first integrated circuits comprises drivers, repeaters, and circuits with high interconnect loading.

12. The microelectronic device of claim 1, wherein the first integrated circuitry and the second integrated circuitry are within a single component.

13. A microelectronic device comprising:
a first transistor fm having a height which sets the baseline performance for first integrated circuitry within the microelectronic device;
a second transistor fin having a height greater than the first transistor fin height, which sets a performance for second integrated circuitry within the microelectronic device, wherein the performance set by the second transistor fin differs from the baseline performance; and
a third transistor fm having a height less than the first transistor fin height, which sets a performance for third integrated circuitry within the microelectronic device, wherein the performance of the set by the third transistor fm differs from the baseline performance and the performance set by the second transistor fin.

14. The microelectronic device of claim 13, wherein the second transistor fin height comprises a height of between about 1.2 and 1.6 times the first transistor fin height.

15. The microelectronic device of claim 14, wherein the second transistor fm height comprises a height of about 1.4 times the first transistor fin height.

16. The microelectronic device of claim 14, wherein the second integrated circuitry comprises a static random access memory.

17. The microelectronic device of claim 14, wherein the second integrated circuitry comprises register file circuitry.

18. The microelectronic device of claim 13, wherein the third transistor fin height comprises a height of between about 0.85 and 0.5 times the first transistor fin height.

19. The microelectronic device of claim 18, wherein the third transistor fin height comprises a height of about 0.7 times the first transistor fin height.

20. The microelectronic device of claim 18, wherein the third integrated circuitry within the microelectronic device comprises second integrated circuits having a total capacitive load of greater than the total interconnection load of connecting lines within the microelectronic device.

21. The microelectronic device of claim 19, wherein the third integrated circuits comprise register files, latches, complex gates, and circuits with high device fanout.

22. The microelectronic device of claim 13, wherein the first integrated circuitry within the microelectronic device comprises first integrated circuits having total capacitive load less than the total interconnection of connecting lines within the microelectronic device.

23. The microelectronic device of claim 22, wherein the first integrated circuits drivers, repeaters, and circuits with high interconnect loading.

24. The microelectronic device of claim 13, wherein the first integrated circuitry and the second integrated circuitry are within a single component.

25. The microelectronic device of claim 13, wherein the first integrated circuitry and the third integrated circuitry are within a single component.

26. A method of forming transistor fins of differing height, comprising:
providing a substrate with a plurality of isolation regions formed therein;
patterning a blocking material on the substrate to mask a portion of the plurality of isolation regions;
etching through the blocking material;
etching the isolation regions to recess the dielectric material therein, wherein etching through the blocking layer delays the etching of the isolation regions masked by the blocking material.

27. The method of claim 26, wherein providing a substrate with plurality of isolation regions comprises:
providing a substrate;
patterning a mask on the substrate, wherein the mask has a plurality of openings therein to expose portions of the substrate;
etching the substrate through the plurality of openings to form a plurality of trenches;
removing the mask; and
deposition a dielectric material within the plurality of trenches.
